(19) United States
(12) Patent Application Publication
(10) Pub. No.: US 2023/0238370 A1
(43) Pub. Date: Jul. 27, 2023

(54) DISPLAY DEVICE

(71) Applicant: Samsung Display Co., LTD., Yongin-si (KR)

(72) Inventors: Beom Soo SHIN, Yongin-si (KR); Min Seok LEE, Yongin-si (KR)

(73) Assignee: Samsung Display Co., LTD., Yongin-si (KR)

(21) Appl. No.: 17/946,676

(22) Filed: Sep. 16, 2022

(30) Foreign Application Priority Data
Jan. 26, 2022 (KR) 10-2022-0011609

(51) Int. Cl. H01L 25/16; H01L 33/60

(52) U.S. Cl. CPC H01L 25/167; H01L 33/60; H01L 33/44

(57) ABSTRACT

A display device includes a first electrode and a second electrode disposed on a substrate; a first bank disposed on the substrate, the first bank protruding in a thickness direction of the substrate; a light emitting element disposed on the first electrode and the second electrode; a reflective electrode disposed on the first bank; a second bank disposed on the first bank; and a color conversion layer disposed in an area surrounded by the second bank.

### CROSS-REFERENCE TO RELATED APPLICATION(S)

This application claims priority to and benefits of Korean patent application No. 10-2022-0011609 under 35 U.S.C. § 119 filed on Jan. 26, 2022 in the Korean Intellectual Property Office, the entire contents of which are incorporated herein by reference.

### BACKGROUND

### 1. Technical Field

The disclosure generally relates to a display device.

### 2. Description of the Related Art

Recently, as interest in information displays is increased, research and development of display devices have been continuously conducted.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display device having improved light emission efficiency.

A display device may include a first electrode and a second electrode disposed on a substrate; a first bank disposed on the substrate, the first bank protruding in a thickness direction of the substrate; a light emitting element disposed on the first electrode and the second electrode; a reflective electrode disposed on the first bank; a second bank disposed on the first bank; and a color conversion layer disposed in an area surrounded by the second bank.

The second bank may be disposed on a top surface of the first bank and not disposed on any side surface of the first bank.

The first bank may have a first height, and the second bank may have a second height. The first height may be greater than the second height.

The second height may be about 0.3 times or less than the first height.

The first bank may have a first width, and the second bank may have a second width. The first width may be greater than the second width.

A difference between the first width and the second width may be about 3 μm or less.

The display device may further include an insulating pattern disposed on the substrate, the insulating pattern protruding in the thickness direction of the substrate. A portion of the reflective electrode may be disposed on the insulating pattern. The insulating pattern may include a first insulating pattern and the second insulating pattern. The light emitting element may be disposed between the first insulating pattern and the second insulating pattern.

The first bank may have a first width, the second bank may have a second width, and the insulating pattern may have a third width. The first width may be greater than the second width, and the third width may be greater than the first width.

The second bank may be disposed on a side surface and a top surface of the first bank.

The second bank may include an organic material that transmits light.

The first bank may have a first width, and the second bank may have a second width. The second width may be greater than the first width.

A difference between the first width and the second width may be about 3 μm or less.

The light emitting element may be disposed in an area surrounded by the first bank.

At least a portion of the reflective electrode may be disposed between the first bank and the second bank.

The color conversion layer may include a color conversion particle that converts a color of light. A surface of the second bank may face the first bank and the reflective electrode, and another surface of the second bank may be exposed toward the color conversion layer.

The color conversion layer may contact the second bank.

The reflective electrode may be disposed on a side surface of the first bank.

The display device may further include a color filter layer disposed on the color conversion layer, the color filter layer may selectively transmit light.

A display device may include a first electrode and a second electrode disposed on a substrate; a partition wall disposed on the substrate, the partition wall protruding in a thickness direction of the substrate; a light emitting element disposed between the first electrode and the second electrode; a reflective electrode disposed on the partition wall; a bank disposed on the partition wall; and a color conversion layer disposed in an area surrounded by the bank, wherein the partition wall may include a first part and a second part, and a width of the first part of the partition wall may be greater than a width of the second part of the partition wall.

A height of the first part of the partition wall may be less than a height of the second part of the partition wall.

### BRIEF DESCRIPTION OF THE DRAWINGS

The above and other aspects and features of the disclosure will become more apparent by describing in detail embodiments thereof with reference to the attached drawings, in which:

FIGS. 1 and 2 are schematic perspective and sectional views illustrating a light emitting element in accordance with an embodiment.

FIGS. 3 and 4 are schematic perspective and sectional views illustrating a light emitting element in accordance with an embodiment.

FIG. 5 is a schematic plan view illustrating a display device in accordance with an embodiment.

FIG. 6 is a schematic plan view illustrating a pixel in accordance with an embodiment.

FIGS. 7 to 9 are schematic sectional views illustrating sub-pixels in accordance with embodiments.

FIG. 10 is a schematic sectional view illustrating first to third sub-pixels in accordance with an embodiment.

FIG. 11 is a schematic sectional view illustrating a sub-pixel in accordance with an embodiment.

### DETAILED DESCRIPTION OF THE EMBODIMENTS

The disclosure is applicable to various changes and different shapes, and is not limited to particular examples. Thus, the examples are not limited to certain shapes but apply to all variations and changes and equivalent materials and replacements.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

It will be understood that when an element is referred to as being “between” two elements, it can be the only element between the two elements, or one or more intervening elements may also be present. Like reference numerals refer to like elements throughout.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms “first”, “second”, etc. may be used herein to describe various elements, these elements should not be limited by these terms. These terms are only used to distinguish one element from another element. Thus, a “first” element discussed below could also be termed a “second” element without departing from the teachings of the disclosure.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

It will be further understood that the terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Further, an expression that an element such as a layer, region, substrate or plate is placed “on” or “above” another element indicates not only a case where the element is placed “directly on” or “just above” the other element but also a case where a further element or elements is/are interposed between the element and the other element. An expression that an element such as a layer, region, substrate or plate is placed “beneath” or “below” another element indicates not only a case where the element is placed “directly beneath” or “just below” the other element but also a case where a further element or elements is/are interposed between the element and the other element.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The disclosure generally relates to a display device. Hereinafter, a display device in accordance with an embodiment will be described with reference to the accompanying drawings.

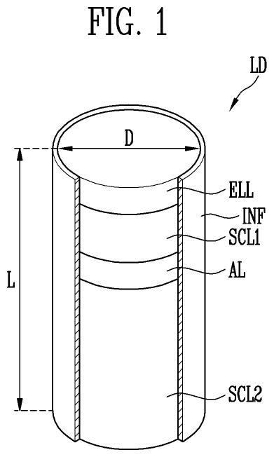

A light emitting element LD in accordance with an embodiment will be described with reference to FIGS. 1 to 4.

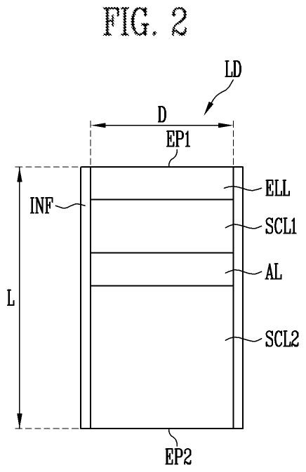

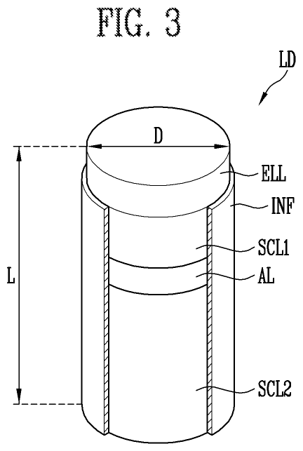

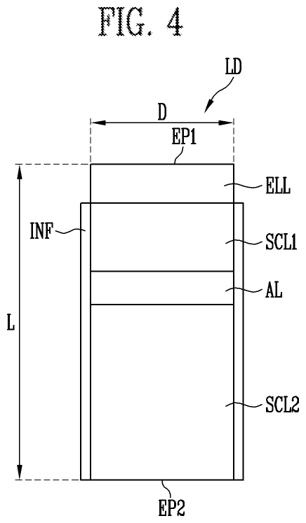

FIGS. 1 and 2 are schematic perspective and sectional views illustrating a light emitting element in accordance with an embodiment. FIGS. 3 and 4 are schematic perspective and sectional views illustrating a light emitting element in accordance with an embodiment.

Although a pillar-shaped light emitting element LD is illustrated in FIGS. 1 to 4, the kind and/or shape of the light emitting element LD is not limited thereto.

The light emitting element LD may include a second semiconductor layer SCL2, a first semiconductor layer SCL1, and an active layer AL interposed between the first and second semiconductor layers SCL1 and SCL2. For example, in case that assuming that an extending direction of the light emitting element LD is a length L direction, the light emitting element LD may include the first semiconductor layer SCL1, the active layer AL, and the second semiconductor layer SCL2, which are sequentially stacked along the length L direction. The light emitting element LD may further include an electrode layer ELL and an insulative film INF.

The light emitting element LD may be provided in a pillar shape extending along one direction or a direction. The light emitting element LD may have a first end portion EP1 and a second end portion EP2. The first semiconductor layer SCL1 may be adjacent to the first end portion EP1, and the second semiconductor layer SCL2 may be adjacent to the second end portion EP2. The electrode layer ELL may be adjacent to the first end portion EP1.

The light emitting element LD may be a light emitting element manufactured in a pillar shape through an etching process, or the like within the spirit and the scope of the disclosure. In this specification, the term “pillar shape” may include a rod-like shape or bar-like shape, which is long in the length L direction (for example, its aspect ratio is greater than 1), such as a cylinder or a polyprism, and the shape of its section is not particularly limited. For example, a length L of the light emitting element LD may be greater than a diameter D (or a width of a cross-section) of the light emitting element LD.

The light emitting element LD may have a size of nanometer scale to micrometer scale. For example, the light emitting element LD may have a diameter D (or width) in a range of nanometer scale to micrometer scale and/or a length L in a range of nanometer scale to micrometer scale. However, the size of the light emitting element LD is not limited thereto.

The first semiconductor layer SCL1 may be a first conductivity type semiconductor layer. The first semiconductor layer SCL1 is disposed on the active layer AL, and may include a semiconductor layer having a type different from a type of the second semiconductor layer SCL2. For example, the first semiconductor layer SCL1 may include a P-type semiconductor layer. In an example, the first semiconductor layer SCL1 may include at least one semiconductor material among InAlGaN, GaN, AlGaN, InGaN, AlN, and InN, and include a P-type semiconductor layer doped with a first conductivity type dopant such as Mg. However, the material constituting the first semiconductor layer SCL1 is not limited thereto. The first semiconductor layer SCL1 may be formed of various materials.

The active layer AL is disposed between the first semiconductor layer SCL1 and the second semiconductor layer SCL2, and may be formed in a single-quantum well structure or a multi-quantum well structure. The position of the active layer AL is not limited to a specific example, and may be variously changed according to the kind of the light emitting element LD.

A clad layer doped with a conductive dopant may be formed on the top and/or the bottom of the active layer AL. For example, the clad layer may be formed as an AlGaN layer or an InAlGaN layer. In an embodiment, a material such as AlGaN or AlInGaN may be used to form the active layer AL. The active layer AL may be formed of various materials.

The second semiconductor layer SCL2 may be a second conductivity type semiconductor layer. The second semiconductor layer SCL2 is disposed on the active layer AL, and may include a semiconductor layer having a type different from the type of the first semiconductor layer SCL1. For example, the second semiconductor layer SCL2 may include an N-type semiconductor layer. For example, the second semiconductor layer SCL2 may include any one semiconductor material among InAlGaN, GaN, AlGaN, InGaN, AlN, and InN, and include an N-type semiconductor layer doped with a second conductivity type dopant such as Si, Ge or Sn. However, the material constituting the second semiconductor layer SCL2 is not limited thereto. The second semiconductor layer SCL2 may be formed of various materials.

In case that a voltage which is a threshold voltage or more is applied to both ends of the light emitting element LD, the light emitting element LD emits light as electron-hole pairs are combined in the active layer AL. The light emission of the light emitting element LD is controlled by using such a principle, so that the light emitting element LD can be used as a light source for various light emitting devices, including a pixel of a display device.

The insulative film INF may be disposed on a surface of the light emitting element LD. The insulative film INF may be formed on the surface of the light emitting element LD to surround an outer circumferential surface of at least the active layer AL. The insulative film INF may further surround an area or areas of the first and second semiconductor layers SCL1 and SCL2. The insulative film INF may be formed as a single layer or a multi-layer. However, the disclosure is not limited thereto, and the insulative film INF may be formed of layers. For example, the insulative film INF may include a first insulating layer including a first material and a second insulating layer including a second material different from the first material.

The insulative film INF may expose both the end portions of the light emitting element LD, which have different polarities. For example, the insulative film INF may expose one end or an end of each of the electrode layer ELL and the second semiconductor layer SCL2, which are respectively adjacent to the first and second end portions EP1 and EP2 of the light emitting element LD.

The insulative film INF may be a single layer or a multi-layer, including one insulating material among silicon oxide (SiOₓ), silicon nitride (SiNₓ), silicon oxynitride (SiOₓN_{y}), aluminum oxide (AlOₓ), and titanium oxide (TiOₓ). However, the disclosure is not necessarily limited to the above-described example. For example, in accordance with an embodiment, the insulative film INF may be omitted.

In accordance with an embodiment, in case that the insulative film INF is provided to cover the surface of the light emitting element LD, for example, the outer circumferential surface of the active layer AL, the electrical stability of the light emitting element LD can be ensured. Also, in case that the insulative film INF is provided on the surface of the light emitting element LD, a surface defect of the light emitting element LD is minimized, thereby improving the lifetime and efficiency of the light emitting element LD. Even in case that light emitting elements LD are densely disposed, an unwanted short circuit can be prevented from occurring between the light emitting elements LD.

The electrode layer ELL may be disposed on the first semiconductor layer SCL1. The electrode layer ELL may be adjacent to the first end portion EP1. The electrode layer ELL may be electrically connected to the first semiconductor layer SCL1.

A portion of the electrode layer ELL may be exposed. For example, the insulative film INF may expose one surface or a surface of the electrode layer ELL. The electrode layer ELL may be exposed in an area corresponding to the first end portion EP1.

In an embodiment, a side surface of the electrode layer ELL may be exposed (see FIGS. 3 and 4). For example, the insulative film INF may not cover at least a portion of the side surface of the electrode layer ELL while covering a side surface of each of the first semiconductor layer SCL1, the active layer AL, and the second semiconductor layer SCL2. Thus, the electrode layer ELL adjacent to the first end portion EP1 can be readily connected to another component. In an embodiment, the insulating layer INF may expose not only the side surface of the electrode layer ELL but also a portion of a side surface of the first semiconductor layer SCL1 and/or the second semiconductor layer SCL2.

In accordance with an embodiment, the electrode layer ELL may be an ohmic contact electrode. However, the disclosure is not necessarily limited to the above-described example. For example, the electrode layer ELL may be a Schottky contact electrode.

In accordance with an embodiment, the electrode layer ELL may include one of chromium (Cr), titanium (Ti), aluminum (Al), gold (Au), nickel (Ni), and any oxide or ally thereof. However, the disclosure is not necessarily limited to the above-described example. In an embodiment, the electrode layer ELL may be substantially transparent. For example, the electrode layer ELL may include indium tin oxide (ITO). Accordingly, emitted light can be transmitted through the electrode layer ELL.

The structure, shape, and the like of the light emitting element LD are not limited to the above-described example. In an embodiment, the light emitting element LD may have various structures and various shapes. For example, the light emitting element LD may further include an additional electrode layer which is disposed on one surface or a surface of the second semiconductor layer SCL2 and is adjacent to the second end portion EP2.

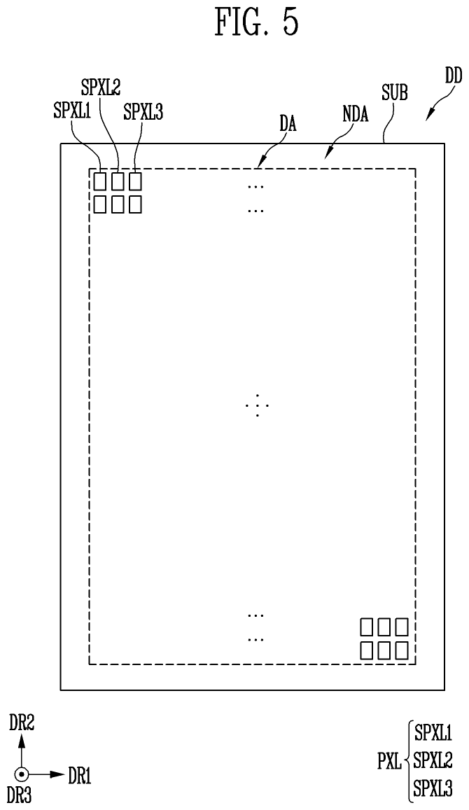

FIG. 5 is a schematic plan view illustrating a display device in accordance with an embodiment.

The display device DD emits light. Referring to FIG. 5, the display device DD may include a substrate SUB and pixels PXL disposed on the substrate SUB. Although not shown in the drawing, the display device DD may further include a driving circuit (for example, a scan driver and a data driver) for driving the pixels PXL, lines, and pads.

The display device DD may include a display area DA and a non-display area NDA. The non-display area NDA may mean an area except the display area DA. The non-display area NDA may surround or may be adjacent to at least a portion of the display area DA.

The substrate SUB may constitute a base member of the display device DD. The substrate SUB may be a rigid or flexible substrate or film. For example, the substrate SUB may be a rigid substrate made of glass or tempered glass, a flexible substrate (or thin film) made of a plastic or metal material, or at least one insulating layer. The material and/or property of the substrate SUB is not particularly limited. In an embodiment, the substrate may be substantially transparent. The term “substantially transparent” may mean that light can be transmitted with a given transmittance or more. In an embodiment, the substrate SUB may be translucent or opaque. Also, the substrate SUB may include a reflective material in an embodiment.

The display area DA may mean an area in which the pixels PXL are disposed. The non-display area NDA may mean an area in which the pixels PXL are not disposed. The driving circuit, the lines, and the pads, which are connected to the pixels PXL of the display area DA, may be disposed in the non-display area NDA.

In an example, the pixels PXL may be arranged or disposed according to a stripe arrangement structure, a PENTILE™ arrangement structure, or the like within the spirit and the scope of the disclosure. However, the disclosure is not limited thereto, and various embodiments may be applied in the disclosure.

In accordance with an embodiment, the pixel PXL may include a first sub-pixel SPXL1, a second sub-pixel SPXL2, and a third sub-pixel SPXL3. Each of the first sub-pixel SPXL1, the second sub-pixel SPXL2, and the third sub-pixel SPXL3 may be a sub-pixel. At least one first sub-pixel SPXL1, at least one second sub-pixel SPXL2, and at least one third sub-pixel SPXL3 may constitute one pixel unit emitting lights of various colors.

For example, each of the first sub-pixel SPXL1, the second sub-pixel SPXL2, and the third sub-pixel SPXL3 may emit light of a color. For example, the first sub-pixel SPXL1 may be a red pixel emitting light of red (for example, a first color), the second sub-pixel SPXL2 may be a green pixel emitting light of green (for example, a second color), and the third sub-pixel SPXL3 may be a blue pixel emitting light of blue (for example, a third color). However, the color, kind, and/or number of first, second, and third sub-pixels SPXL1, SPXL2, and SPXL3 constituting each pixel unit are not limited to a specific example.

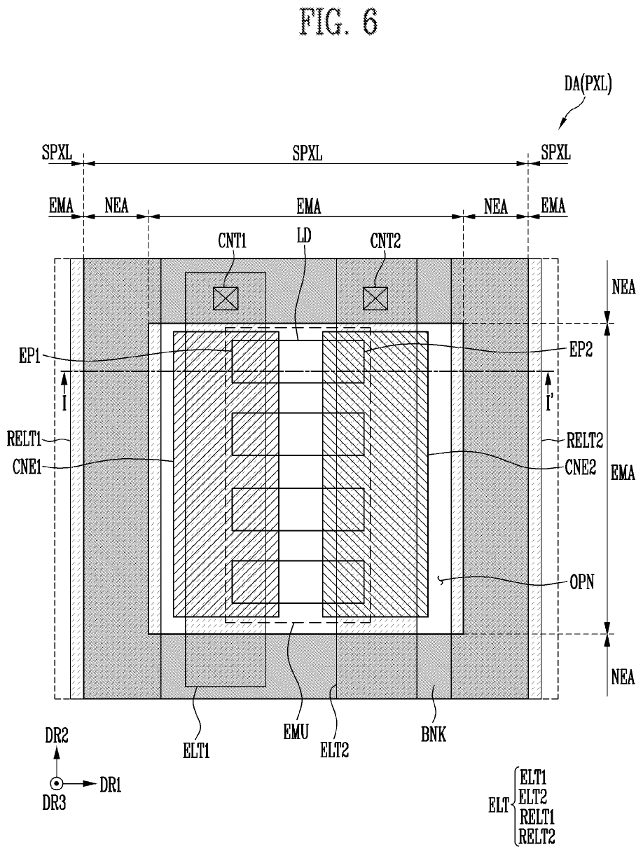

Hereinafter, a structure of a pixel PXL will be described with reference to FIGS. 6 to 11.

FIGS. 6 to 11 are views illustrating a pixel PXL (or sub-pixel SPXL) in accordance with an embodiment.

FIG. 6 is a schematic plan view illustrating a pixel in accordance with an embodiment.

Referring to FIG. 6, the pixel PXL may include sub-pixels SPXL adjacent to each other. The sub-pixel SPXL may be one of the first to third sub-pixels SPXL1, SPXL2, and SPXL3 described above with reference to FIG. 5. For example, in an embodiment, the sub-pixels SPXL may be adjacent to each other in a first direction DR1.

The sub-pixel SPXL (or the pixel PXL) may include an emission area EMA and a non-emission area NEA. The sub-pixel SPXL may include a bank BNK, an alignment electrode ELT, light emitting elements LD, a first contact electrode CNE1, and a second contact electrode CNE2.

The emission area EMA may overlap an opening OPN defined by the bank BNK in case that viewed in a plan view. The light emitting elements LD may be disposed in the emission area EMA.

The light emitting elements LD may not be disposed in the non-emission area NEA. A portion of the non-emission area NEA may overlap the bank BNK in case that viewed in a plan view.

The bank BNK may form (or provide) the opening OPN. For example, the bank BNK may have a shape protruding in a thickness direction of the substrate SUB (for example, a third direction DR3), and have a shape surrounding an area. Accordingly, the opening OPN in which the bank BNK is not disposed can be formed.

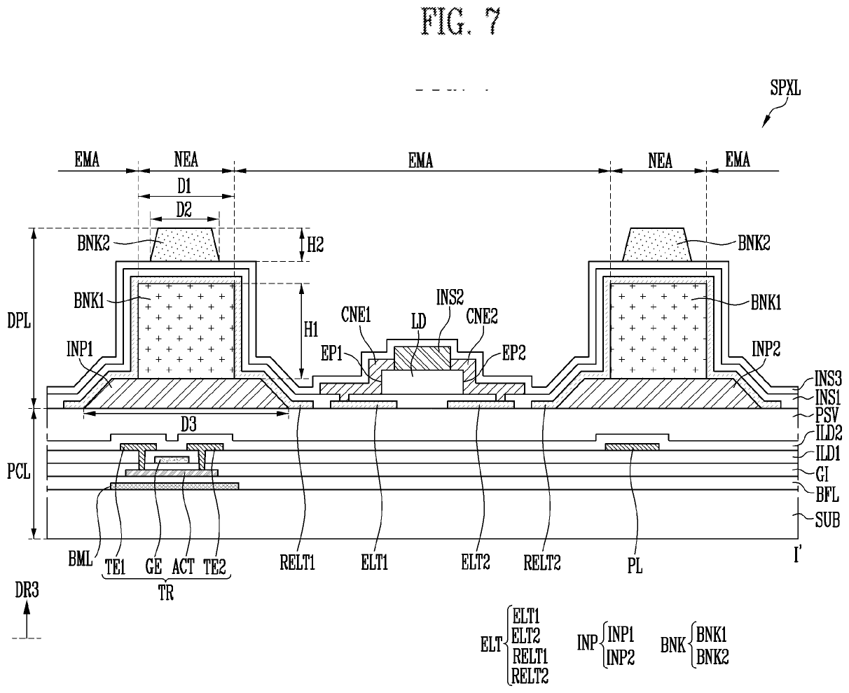

The bank BNK may form a space. The bank BNK may have a shape surrounding a partial area in case that viewed in a plan view. The space may mean an area in which a fluid can be accommodated. In accordance with an embodiment, the bank BNK may include a first bank (see ‘BNK1’ shown in FIG. 7) and a second bank (see ‘BNK2’ shown in FIG. 7).

In accordance with an embodiment, an ink including the light emitting elements LD may be provided in a space defined by the bank BNK (for example, the first bank BNK1), so that the light emitting elements LD are disposed in the opening OPN.

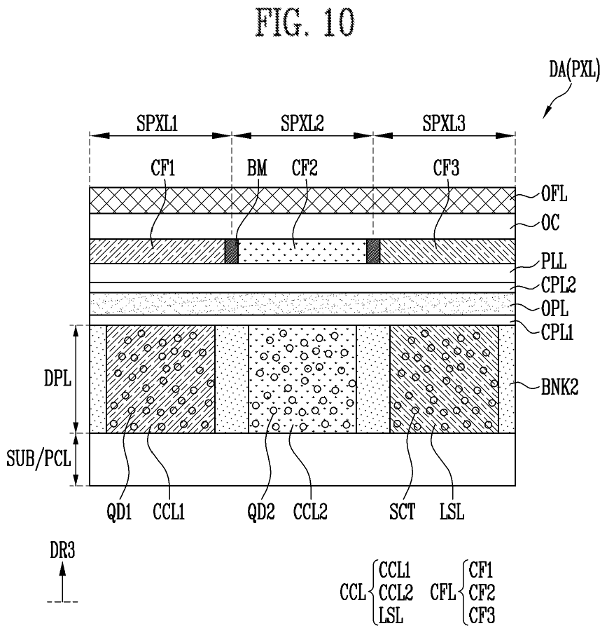

In accordance with an embodiment, a color conversion layer (see ‘CCL’ shown in FIG. 10) may be disposed (or patterned) in a space defined by the bank BNK (for example, the second bank BNK2). This will be described in detail later.

The bank BNK may define the emission area EMA and the non-emission area NEA. The bank BNK may surround at least a portion of the emission area EMA in case that viewed in a plan view. For example, an area in which the bank BNK is disposed may be the non-emission area NEA. An area in which the light emitting elements LD are disposed as an area in which the bank BNK is not disposed may be the emission area EMA.

The alignment electrode ELT may include an alignment electrode and a reflective electrode. In accordance with an embodiment, the alignment electrode may include a first electrode ELT1 and a second electrode ELT2. The reflective electrode may include a first reflective electrode RELT1 and a second reflective electrode RELT2.

The alignment electrode ELT may be a single layer or a multi-layer. For example, the alignment electrode ELT may include at least one reflective electrode layer including a reflective conductive material, and selectively further include at least one transparent electrode layer and/or at least one conductive capping layer. In an embodiment, the alignment electrode ELT may include one of silver (Al), magnesium (Mg), aluminum (Al), platinum (Pt), palladium (Pd), gold (Au), nickel (Ni), neodymium (Nd), iridium (Ir), chromium (Cr), titanium (Ti), and any alloy thereof. However, the disclosure is not limited to the above-described example, and the alignment electrode ELT may include one of various materials having reflexibility.

The light emitting element LD may be disposed on the alignment electrode ELT. In an embodiment, at least a portion of the light emitting element LD may be disposed between the first electrode ELT1 and the second electrode ELT2. The light emitting element LD may be aligned between the first electrode ELT1 and the second electrode ELT2. The light emitting elements LD may form (or constitute) a light emitting unit EMU. The light emitting unit EMU may mean a unit including adjacent light emitting elements LD.

In an embodiment, the light emitting elements LD may be aligned in various manners. For example, an embodiment in which the light emitting elements LD are aligned in parallel between the first electrode ELT1 and the second electrode ELT2 is illustrated in FIG. 6. However, the disclosure is not necessarily limited to the above-described example. For example, the light emitting elements LD may be aligned in a series or series/parallel hybrid structure, and the number of units connected in series and/or parallel is not particularly limited.

The first electrode ELT1 and the second electrode ELT2 may be spaced apart from each other. For example, the first electrode ELT1 and the second electrode ELT2 may be space apart from each other along the first direction DR1 in the emission area EMA, and each of the first electrode ELT1 and the second electrode ELT2 may extend along a second direction DR2.

In accordance with an embodiment, the first electrode ELT1 and the second electrode ELT2 are electrodes for aligning the light emitting elements LD. The first electrode ELT1 may be a first alignment electrode, and the second electrode ELT2 may be a second alignment electrode.

The first electrode ELT1 and the second electrode ELT2 may be respectively supplied (or provided) with a first alignment signal and a second alignment signal in a process of aligning the light emitting elements LD. For example, the ink including the light emitting elements LD may be supplied (or provided) to the opening OPN defined by the bank BNK (for example, the first bank BNK1), the first alignment signal may be supplied to the first electrode ELT1, and the second alignment signal may be supplied to the second electrode ELT2. The first alignment signal and the second alignment signal may have different waveforms, different potentials, and/or different phases. Accordingly, an electric field is formed between (or on) the first electrode ELT1 and the second electrode ELT2, so that the light emitting elements LD can be aligned between the first electrode ELT1 and the second electrode ELT2, based on the electric field.

The first electrode ELT1 may be electrically connected to a circuit element (for example, a transistor (see ‘TR’ shown in FIG. 7)) through a first contact part CNT1. In an embodiment, the first electrode ELT1 may provide an anode signal for allowing the light emitting element LD to emit light. The first electrode ELT1 may provide the first alignment signal for aligning the light emitting element LD.

The second electrode ELT2 may be electrically connected to a power line (see ‘PL’ shown in FIG. 7) through a second contact part CNT2. In an embodiment, the second electrode ELT2 may provide a cathode signal (for example, a ground signal) for allowing the light emitting element LD to emit light. The second electrode ELT2 may provide the second alignment signal for aligning the light emitting element LD.

The positions of the first contact part CNT1 and the second contact part CNT2 are not limited to positions shown in FIG. 6, and may be appropriately variously determined and changed.

The first reflective electrode RELT1 and the second reflective electrode RELT2 may be disposed on the bank BNK. For example, the first reflective electrode RELT1 and the second reflective electrode RELT2 may be disposed on the first bank BNK1. At least apportion of each of the first reflective electrode RELT1 and the second reflective electrode RELT2 may be disposed (or interposed) between the first bank BNK1 and the second bank BNK2. Accordingly, the first reflective electrode RELT1 and the second reflective electrode RELT2 are formed on the first bank BNK1, to reflect light emitted from the light emitting element LD. Thus, the emitted light is recycled, so that the light emission efficiency of the light emitting elements LD (or the pixel PXL) can be improved.

In an embodiment, the first reflective electrode RELT1 and the second reflective electrode RELT2 may be patterned through a same process as the first electrode ELT1 and the second electrode ELT2. The first reflective electrode RELT1 and the second reflective electrode RELT2 may be formed at the same time as the first electrode ELT1 and the second electrode ELT2, and include a same material or a similar material as the first electrode ELT1 and the second electrode ELT2. Thus, the number of masks can be decreased, and a manufacturing process can be simplified. Accordingly, process cost can be saved.

In accordance with an embodiment, the first reflective electrode RELT1 and the second reflective electrode RELT2 may be patterned through a process different from a process through which the first electrode ELT1 and the second process ELT2 are patterned. For example, the first reflective electrode RELT1 and the second reflective electrode RELT2 may be disposed on the first bank BNK1 after the light emitting element LD is aligned as the first electrode ELT1 and the second process ELT2 are formed. It will be apparent that the first reflective electrode RELT1 and the second reflective electrode RELT2 have reflexibility, including a material that reflects light.

The light emitting element LD may emit light, based on an electrical signal provided thereto. For example, the light emitting element LD may provide light, based on a first electrical signal provided from the first electrode ELT1 and the first contact electrode CNE1 and a second electrical signal provided from the second electrode ELT2 and the second contact electrode CNE2. However, the disclosure is not necessarily limited to the above-described example.

A first end portion EP1 of the light emitting element LD may be disposed adjacent to the first electrode ELT1, and a second end portion EP2 may be disposed adjacent to the second electrode ELT2. The first end portion EP1 may or may not overlap the first electrode ELT1. The second end portion EP2 may or may not overlap the second electrode ELT2.

In an embodiment, the first end portion EP1 of each of the light emitting elements LD may be electrically connected to the first electrode ELT1 through the first contact electrode CNE1. In an embodiment, the first end portion EP1 of each of the light emitting elements LD may be connected to or directly connected to the first electrode ELT1. In an embodiment, the first end portion EP1 of each of the light emitting elements LD is electrically connected to only the first contact electrode CNE1, and may not be connected to the first electrode ELT1.

Similarly, the second end portion EP2 of each of the light emitting elements LD may be electrically connected to the second electrode ELT2 through the second contact electrode CNE2. In an embodiment, the second end portion EP2 of each of the light emitting elements LD may be connected to or directly connected to the second electrode ELT2. In an embodiment, the second end portion EP2 of each of the light emitting elements LD is electrically connected to only the second contact electrode CNE2, and may not be connected to the second electrode ELT2.

The first contact electrode CNE1 and the second contact electrode CNE2 may be respectively disposed on the first end portions EP1 and the second end portions EP2 of the light emitting elements LD.

The first contact electrode CNE1 may be disposed on the first end portions EP1 of the light emitting elements LD to be electrically connected to the first end portions EP1. In an embodiment, the first contact electrode CNE1 may be disposed on the first electrode ELT1 to be electrically connected to the first electrode ELT1. The first end portions EP1 of the light emitting elements LD may be connected to the first electrode ELT1 through the first contact electrode CNE1.

The second contact electrode CNE2 may be disposed on the second end portions EP2 of the light emitting elements LD to be electrically connected to the second end portions EP2. In an embodiment, the second contact electrode CNE2 may be disposed on the second electrode ELT2 to be electrically connected to the second electrode ELT2. The second end portions EP2 of the light emitting elements LD may be connected to the second electrode ELT2 through the second contact electrode CNE2.

Hereinafter, a sectional structure of the sub-pixel SPXL will be described with reference to FIGS. 7 to 11.

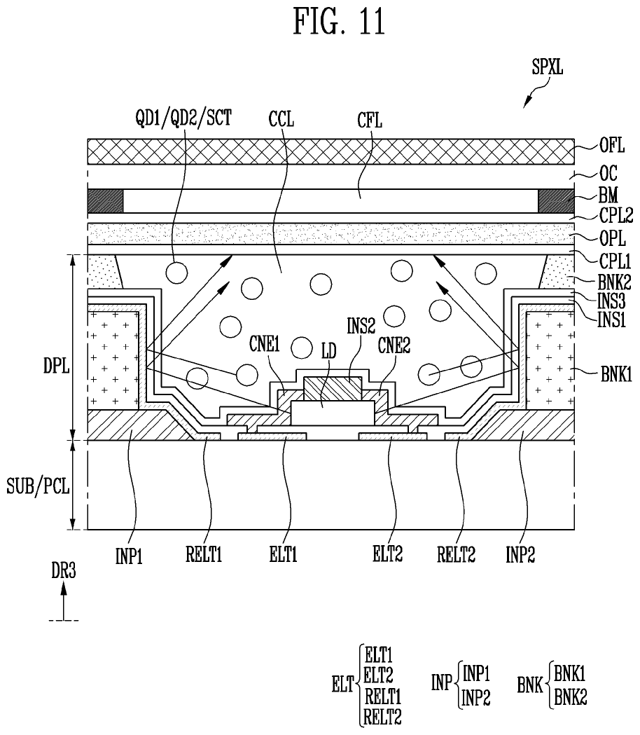

First, a pixel circuit layer PCL and a display element layer DPL of the sub-pixel SPXL will be described with reference to FIGS. 7 to 9, a color conversion layer CCL, an optical layer OPL, a color filter layer CFL, and an outer film layer OFL of the pixel PXL will be described with reference to FIG. 10, and the display element layer DPL and the color conversion layer CCL will be described together with reference to FIG. 11.

FIGS. 7 to 9 are schematic sectional views illustrating sub-pixels in accordance with embodiments. FIGS. 7 to 9 are schematic sectional views taken along line I-I′ shown in FIG. 6.

FIG. 7 may illustrate a sub-pixel SPXL in accordance with a first embodiment.

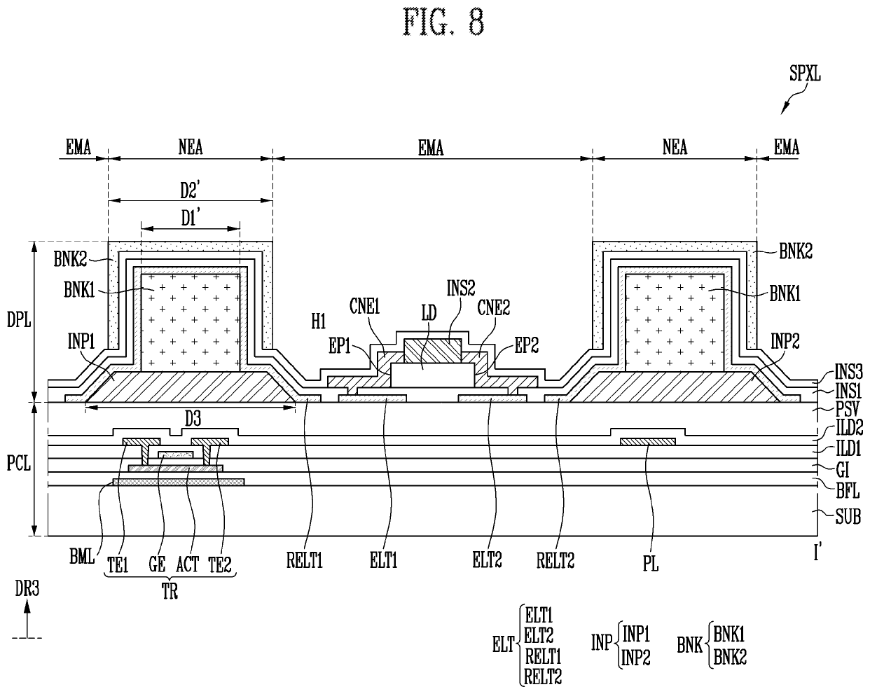

FIG. 8 may illustrate a sub-pixel SPXL in accordance with a second embodiment.

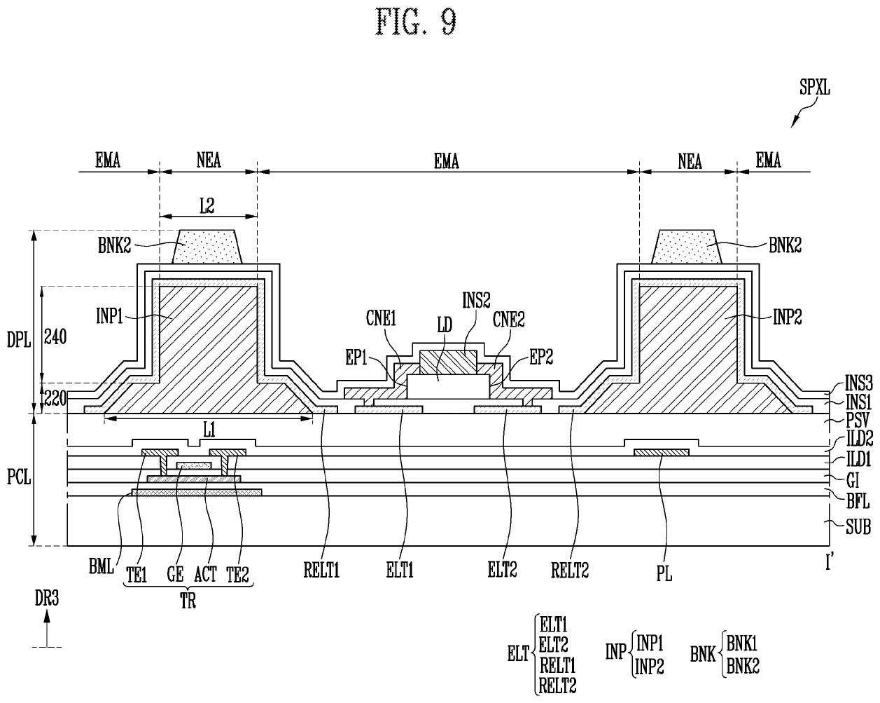

FIG. 9 may illustrate a sub-pixel SPXL in accordance with a third embodiment.

First, the sub-pixel SPXL in accordance with the first embodiment will be described with reference to FIG. 7.

Referring to FIG. 7, the sub-pixel SPXL may include a substrate SUB, a pixel circuit layer PCL, and a display element layer DPL.

The substrate SUB may form (or constitute) a base member of the sub-pixel SPXL. The substrate SUB may provide an area on which the pixel circuit layer PCL and the display element layer DPL can be disposed.

The pixel circuit layer PCL may be disposed on the substrate SUB. The pixel circuit layer PCL may include a lower auxiliary electrode BML, a buffer layer BFL, a transistor TR, a gate insulating layer GI, a first interlayer insulating layer ILD1, a second interlayer insulating layer ILD2, and a protective layer PSV.

The lower auxiliary electrode BML may be disposed on the substrate SUB. The lower auxiliary electrode BML may serve as a path through which an electrical signal is moved. In an embodiment, a portion of the lower auxiliary electrode BML may overlap the transistor TR in case that viewed in a plan view.

The buffer layer BFL may be disposed on the substrate SUB. The buffer layer BFL may cover the lower auxiliary electrode BML. The buffer layer BFL may prevent an impurity from being diffused from the outside. The buffer layer BFL may include one of silicon oxide (SiOₓ), silicon nitride (SiNₓ), silicon oxynitride (SiOₓN_{y}), aluminum oxide (AlOₓ), and titanium oxide (TiOₓ). However, the disclosure is not limited to the above-described example.

The transistor TR may be a thin film transistor. In accordance with an embodiment, the transistor TR may be a driving transistor. The transistor TR may be electrically connected to a light emitting element LD. The transistor TR may be electrically connected to a first end portion EP1 of the light emitting element LD.

The transistor TR may include an active layer ACT, a first transistor electrode TE1, a second transistor electrode TE2, and a gate electrode GE.

The active layer ACT may mean a semiconductor layer. The active layer ACT may be disposed on the buffer layer BFL. The active layer ACT may include at least one of poly-silicon, Low Temperature Polycrystalline Silicon (LTPS), amorphous silicon, and an oxide semiconductor.

The active layer ACT may include a first contact region in contact with the first transistor electrode TE1 and a second contact region in contact with the second transistor electrode TE2. The first contact region and the second contact region may correspond to a semiconductor pattern doped with an impurity. A region between the first contact region and the second contact region may be a channel region. The channel region may correspond to an intrinsic semiconductor pattern undoped with the impurity.

The gate electrode GE may be disposed on the gate insulating layer GI. A position of the gate electrode GE may correspond to that of the channel region of the active pattern ACT. For example, the gate electrode GE may be disposed on the channel region of the active pattern ACT with the gate insulating layer GI interposed therebetween.

The gate insulating layer GI may be disposed on the buffer layer BFL. The gate insulating layer GI may cover the active pattern ACT. The gate insulating layer GI may include one of silicon oxide (SiOₓ), silicon nitride (SiNₓ), silicon oxynitride (SiOₓN_{y}), aluminum oxide (AlOₓ), and titanium oxide (TiOₓ). However, the disclosure is not limited to the above-described example.

The first interlayer insulating layer ILD1 may be disposed on the gate insulating layer GI. The first interlayer insulating layer ILD1 may cover the gate electrode GE. The first interlayer insulating layer ILD1 may include one of silicon oxide (SiOₓ), silicon nitride (SiNₓ), silicon oxynitride (SiOₓN_{y}), aluminum oxide (AlOₓ), and titanium oxide (TiOₓ). However, the disclosure is not necessarily limited to the above-described example.

The first transistor electrode TE1 and the second transistor electrode TE2 may be disposed on the first interlayer insulating layer ILD1. The first transistor electrode TE1 may be in contact with the first contact region of the active pattern ACT while penetrating the gate insulating layer GI and the first interlayer insulating layer ILD1, and the second transistor electrode TE2 may be in contact with the second contact region of the active pattern ACT while penetrating the gate insulating layer GI and the first interlayer insulating layer ILD1. In an example, the first transistor electrode TE1 may be a drain electrode, and the second transistor electrode TE2 may be a source electrode. However, the disclosure is not limited thereto.

The first transistor electrode TE1 may be electrically connected to a first electrode ELT1 through a first contact part CNT1 (not shown in FIG. 7) penetrating the protective layer PSV and the second interlayer insulating layer ILD2.

The second interlayer insulating layer ILD2 may be disposed on the first interlayer insulating layer ILD1. The second interlayer insulating layer ILD2 may cover the first transistor electrode TE1, the second transistor electrode TE2 and the power line PL. The second interlayer insulating layer ILD2 may include one of silicon oxide (SiOₓ), silicon nitride (SiNₓ), silicon oxynitride (SiOₓN_{y}), aluminum oxide (AlOₓ), and titanium oxide (TiOₓ). However, the disclosure is not limited to the above-described example.

The protective layer PSV may be disposed on the second interlayer insulating layer ILD2. Although not shown in FIG. 7, the first contact part CNT1 and a second contact part CNT2 may be formed in the protective layer PSV. In an embodiment, the protective layer PSV may be a via layer. The protective layer PSV may include an organic material to planarize a lower step difference. For example, the protective layer PSV may include an organic material such as acrylic resin, epoxy resin, phenolic resin, polyamide resin, polyimide resin, unsaturated polyester resin, poly-phenylene ether resin, poly-phenylene sulfide resin, or benzocyclobutene (BCB). However, the disclosure is not necessarily limited thereto, and the protective layer PSV may include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The display element layer DPL may be disposed on the pixel circuit layer PCL. The display element layer DPL may include an insulating pattern INP, a bank BNK, an alignment electrode ELT, a first insulating layer INS1, a light emitting element LD, a second insulating layer INS2, a first contact CNE1, a second contact electrode CNE2, and a third insulating layer INS3.

The insulating pattern INP may be disposed on the protective layer PSV. The insulating pattern INP may have various shapes in an embodiment. In an embodiment, the insulating pattern INP may protrude in a thickness direction of the substrate SUB. Also, the insulating pattern INP may be formed to have an inclined surface inclined at an angle with respect to the substrate SUB. However, the disclosure is not necessarily limited thereto, and the insulating pattern INP may have a sidewall with a curved shape, a stepped shape, or the like within the spirit and the scope of the disclosure. In an example, the insulating pattern INP may have a section having a semicircular shape, a semi-elliptical shape, or the like within the spirit and the scope of the disclosure.

The insulating pattern INP may function to form a step difference such that light emitting elements LD can be readily aligned in the emission area. In an embodiment, the insulating pattern INP may be a partition wall.

The insulating pattern INP may include a first insulating pattern INP1 and a second insulating pattern INP2. The first insulating pattern INP1 may form a surface on which a first reflective electrode RELT1 is disposed. The first insulating pattern INP1 may be adjacent to a first electrode ELT1. The second insulating pattern INP2 may form a surface on which a second reflective electrode RELT2 is disposed. The second insulating pattern INP2 may be adjacent to a second electrode ELT2.

The insulating pattern INP may include at least one organic material and/or at least one inorganic material. In an example, the insulating pattern INP may include an organic material such as acrylic resin, epoxy resin, phenolic resin, polyamide resin, polyimide resin, unsaturated polyester resin, poly-phenylene ether resin, poly-phenylene sulfide resin, or benzocyclobutene (BCB). However, the disclosure is not necessarily limited thereto, and the insulating pattern INP may include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

A first bank BNK1 may be disposed on the insulating pattern INP. For example, a portion of the first bank BNK1 may be disposed on the first insulating pattern INP1, and a portion of the first bank BNK1 may be disposed on the second insulating pattern INP2. In case that viewed in a plan view, the first bank BNK1 may not overlap the emission area EMA, and may overlap the non-emission area NEA. As described above, the first bank BNK1 may define an opening OPN, and a space in which the light emitting elements LD can be provided may be formed in the opening OPN in a process of supplying the light emitting elements LD.

The first bank BNK1 may protrude in the thickness direction of the substrate SUB (for example, the third direction DR3). The first bank BNK1 may be formed to have an inclined surface inclined at an angle with respect to the substrate SUB. However, the disclosure is not necessarily limited thereto, and the first bank BNK1 may have a sidewall with a curved shape, a stepped shape, or the like within the spirit and the scope of the disclosure. In an example, the first bank BNK1 may have a section having a semicircular shape, a semi-elliptical shape, or the like within the spirit and the scope of the disclosure.

The first bank BNK1 may form a surface on which the first and second reflective electrodes RELT1 and RELT2 are disposed. The first bank BNK1 has a shape further protruding (for example, the thickness direction of the substrate SUB) than the insulating pattern INP, so that a function of the first bank BNK1 as a reflective member of the first and second reflective electrodes RELT1 and RELT2 can be more efficiently exhibited.

The first bank BNK1 may include an organic material such as acrylic resin, epoxy resin, phenolic resin, polyamide resin, polyimide resin, unsaturated polyester resin, poly-phenylene ether resin, poly-phenylene sulfide resin, or benzocyclobutene (BCB). However, the disclosure is not necessarily limited thereto, and the first bank BNK1 may include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The alignment electrode ELT may be disposed on the protective layer PSV, the insulating pattern INP, and the first bank BNK1. The first electrode ELT1 and the second electrode ELT2 may be disposed on the protective layer PSV. The first reflective electrode RELT1 may be disposed on the first insulating pattern INP1 and the first bank BNK1. The second reflective electrode RELT2 may be disposed on the second insulating pattern INP2 and the first bank BNK1. In accordance with an embodiment, the alignment electrode ELT may be deposited in various manners. For example, the alignment electrode ELT may be formed through a photoresist process for patterning a metal line.

The first and second reflective electrodes RELT1 and RELT2 disposed on the insulating pattern INP and the first bank BNK1 may serve as a reflective member. For example, the first and second reflective electrodes RELT1 and RELT2 may at least partially cover side surfaces and/or top surfaces of the first bank BNK1 and the insulating pattern INP. The first and second reflective electrodes RELT1 and RELT2 disposed on the first bank BNK1 and the insulating pattern INP may have a shape corresponding to outer surfaces of the first bank BNK1 and the insulating pattern INP. For example, the first and second reflective electrodes RELT1 and RELT2 disposed on the first bank BNK1 and the insulating pattern INP may include an inclined surface or a curved surface, which has a shape corresponding to shapes of the first bank BNK1 and the insulating pattern INP. Accordingly, the first and second reflective electrodes RELT1 and RELT2 reflect, as a reflective member, light emitted from the light emitting element LD, thereby guiding the light in a display direction of the display device DD (for example, the third direction DR3). Accordingly, the light emission efficiency of the display device DD can be improved.

In accordance with an embodiment, the first and second reflective electrodes RELT1 and RELT2 may have a reflexibility. For example, the first and second reflective electrodes RELT1 and RELT2 may have a reflexibility of 50% or more. By way of example, in an embodiment, the first and second reflective electrodes RELT1 and RELT2 may have a reflexibility of 70% or more. However, the disclosure is not necessarily limited to the above-described example.

The first electrode ELT1 may be electrically connected to the light emitting element LD. The first electrode ELT1 may be electrically connected to the first contact electrode CNE1 through a contact hole formed in the first insulating layer INS1. The first electrode ELT1 may apply an anode signal to the light emitting element LD.

The second electrode ELT2 may be electrically connected to the light emitting element LD. The second electrode ELT2 may be electrically connected to the second contact electrode CNE2 through a contact hole formed in the first insulating layer INS1. The second electrode ELT2 may apply a cathode signal (for example, a ground signal) to the light emitting element LD.

The first insulating layer INS may be disposed on the protective layer PSV and the alignment electrode ELT. For example, the first insulating layer INS1 may cover the first and second electrodes ELT1 and ELT2 and the first and second reflective electrodes RELT1 and RELT2. The first insulating layer INS1 may stabilize connection between electrode components, and reduce external influence. The first insulating layer INS1 may include one of silicon oxide (SiOₓ), silicon nitride (SiNₓ), silicon oxynitride (SiOₓN_{y}), aluminum oxide (AlOₓ), and titanium oxide (TiOₓ). However, the disclosure is not limited to the above-described example.

The light emitting element LD may be disposed on the first insulating layer INS1. In an embodiment, the light emitting element LD may emit light, based on an electrical signal provided from the first contact electrode CNE1 and the second contact electrode CNE2.

The light emitting element LD may be disposed in an area surrounded by the first bank BNK1. The light emitting element LD may be disposed between the first insulating pattern INP1 and the second insulating pattern INP2.

The second insulating layer INS2 may be disposed on the light emitting element LD. The second insulating layer INS2 may cover an active layer AL of the light emitting element LD.

The second insulating layer INS2 may expose at least a portion of the light emitting element LD. For example, the second insulating layer INS2 may not cover a first end portion EP1 and a second end portion EP2 of the light emitting element LD. Accordingly, the first end portion EP1 and the second end portion EP2 of the light emitting element LD may be exposed, and be electrically connected respectively to the first contact electrode CNE1 and the second contact electrode CNE2.

In case that the second insulating layer INS is formed on the light emitting elements LD after the light emitting elements LD are completely aligned, the light emitting elements LD can be prevented from being separated from positions at which the light emitting elements LD are aligned.

The second insulating layer INS2 may be a single layer or a multi-layer, and include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ). However, the disclosure is not limited to the above-described example.

The first contact electrode CNE1 and the second contact electrode CNE2 may be disposed on the first insulating layer INS1. The first contact electrode CNE1 may be electrically connected to the first end portion EP1 of the light emitting element LD. The second contact electrode CNE2 may be electrically connected to the second end portion EP2 of the light emitting element LD.

The first contact electrode CNE1 may be electrically connected to the first electrode ELT1 through a contact hole penetrating the first insulating layer INS1, and the second contact electrode CNE2 may be electrically connected to the second electrode ELT2 through a contact hole penetrating the first insulating layer INS1.

The first contact electrode CNE1 and the second contact electrode CNE2 may include a conductive material. For example, the first contact electrode CNE1 and the second contact electrode CNE2 may include a transparent conductive material including one of Indium Tin Oxide (ITO), Indium Zinc Oxide (IZO), and Indium Tin Zinc Oxide (ITZO). However, the disclosure is not necessarily limited to the above-described example.

In accordance with an embodiment, the first contact electrode CNE1 and the second contact electrode CNE2 may be patterned through a same process at the same time. Accordingly, the first contact electrode CNE1 and the second contact electrode CNE2 may include a same material or a similar material. However, the disclosure is not necessarily limited to the above-described example. After any one of the first contact electrode CNE1 and the second contact electrode CNE2 is patterned, the other of the first contact electrode CNE1 and the second contact electrode CNE2 may be patterned. Accordingly, light emitted from the light emitting elements LD can be emitted to the outside of the display device DD while passing through the first and second contact electrodes CNE1 and CNE2.

The third insulating layer INS3 may be disposed on the first insulating layer INS1, the first contact electrode CNE1, the second contact electrode CNE2, and the second insulating layer INS2. The third insulating layer INS3 may be a single layer or a multi-layer, and include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The second bank BNK2 may be disposed on the third insulating layer INS3. The second bank BNK2 may be disposed on the first bank BNK1 with the first and second reflective electrodes RELT1 and RELT2 interposed therebetween. The second bank BNK2 may be disposed on a top surface of the first bank BNK1 without being disposed on any side surface of the first bank BNK1. In an embodiment, the second bank BNK2 may protrude in the thickness direction of the substrate SUB (for example, the third direction DR3). The bank BNK2 may form an opening OPN. The opening OPN formed by the second bank BNK2 may form a spaced in which a color conversion layer CCL is provided. For example, a desired kind and/or a desired amount of the color conversion layer CCL may be provided (or supplied) in the space partitioned by the second bank BNK2. In accordance with an embodiment, the second bank BNK2 may have suitable liquid repellency such that the color conversion layer CCL can be efficiently formed. For example, the second bank BNK2 may have a surface energy of 30 dyne or less. However, the disclosure is not necessarily limited to the above-described example.

The second bank BNK2 may include an organic material such as acrylic resin, epoxy resin, phenolic resin, polyamide resin, polyimide resin, unsaturated polyester resin, poly-phenylene ether resin, poly-phenylene sulfide resin, or benzocyclobutene (BCB). However, the disclosure is not necessarily limited thereto, and the second bank BNK2 may include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

In accordance with an embodiment, the alignment electrode ELT may not be disposed on the second bank BNK2. The second bank BNK2 may be disposed after the alignment electrode ELT is patterned (or formed), and accordingly, one surface or a surface of the second bank BNK2 may be exposed. By way of example, the one surface or a surface of the second bank BNK2 may not be covered by at least the alignment electrode ELT. For example, the one surface or the surface of the second bank BNK2 may face the first bank BNK1. The one surface or the surface of the second bank BNK2 may face the first reflective electrode RELT1 or the second reflective electrode RELT2. The other surface of the second bank BNK2 may be exposed toward the color conversion layer CCL. Accordingly, the second bank BNK2 having liquid repellency suitable for performing a process is in contact with the color conversion layer CCL. Thus, overflow of the color conversion layer CCL can be prevented, and consequently, the color conversion layer CCL can be efficiently provided.

In an embodiment, each of the first bank BNK1 and the second bank BNK2 may include a material. In an embodiment, the first bank BNK1 and the second bank BNK2 may include a same material or a similar material.

The first bank BNK1 and the second bank BNK2 may overlap each other in case that viewed in a plan view. Accordingly, an area in which the light emitting element LD is disposed and an area in which the color conversion layer CCL is disposed may be substantially equally provided.

The first bank BNK1 may have a first height H1. The second bank BNK2 may have a second height H2. The first height H1 and the second height H2 may mean a maximum height of an object along the thickness direction of the substrate SUB. In accordance with an embodiment, the first height H1 may be greater than the second height H2. In accordance with an embodiment, the second height H2 may be about 0.3 times or less of the first height H1. By way of example, in an embodiment, the second height H2 may be 0.2 times or less of the first height H1. The first and second reflective electrodes RELT1 and RELT2 form a wide reflective wall on the first bank BNK1, thereby further improving the light emission efficiency of the display device DD. The second bank BNK2 may have liquid repellency to define an area in which the color conversion layer CCL is provided. To this end, the second bank BNK2 may not be covered by the first and second reflective electrodes RELT1 and RELT2. For example, the height of the second bank BNK2 on which a reflective surface is not formed is appropriately controlled, thereby forming a wide reflective wall while smoothly performing a process for forming the color conversion layer CCL. Thus, the light emission efficiency of the display device DD can be further improved.

The first bank BNK1 may have a first width D1. The second bank BNK2 may have a second width D2. The first width D1 and the second width D2 may mean lengths of the first bank BNK1 and the second bank BNK2 along a direction in which first banks BNK1 (or second banks BNK2) are spaced apart from each other with the light emitting element LD (or the emission area EMA) interposed therebetween. In accordance with an embodiment, the first width D1 may be greater than the second width D2. For example, the first width D1 is greater than the second width D2, and a difference between the first width D1 and the second width D2 may be about 3 μm or less. By way of example, in an embodiment, the first width D1 is greater than the second width D2, and the difference between the first width D1 and the second width D2 may be about 2 μm or less. By way of example, in an embodiment, the first width D1 is greater than the second width D2, and the difference between the first width D1 and the second width D2 may be about 1 μm or less. In case that the first width D1 and the second width D2 satisfy one of the above-described numerical ranges, process dispersion with respect to arrangement of the color conversion layer CCL can be reduced while preventing a fluid (for example, an ink or the like) for forming the color conversion layer CCL from overflowing in case that the color conversion layer CCL is disposed between the second banks BNK2.

In accordance with an embodiment, the insulating pattern INP may have a third width D3. For example, each of the first insulating pattern INP1 and the second insulating pattern INP2 may have the third width D3. The third width D3 may be greater than the first width D1 and the second width D2. The insulating pattern INP has a width greater than the widths of the first bank BNK1 and the second bank BNK2, so that the light emitting element LD can be more readily disposed at a desired position.

The sub-pixel SPXL in accordance with the second embodiment will be described with reference to FIG. 8. In FIG. 8, descriptions of portions overlapping those described above may be omitted or simplified.

The sub-pixel SPXL in accordance with the second embodiment may be different from the sub-pixel SPXL in accordance with the first embodiment, in that the second bank BNK2 may be disposed on a side surface of the first bank BNK1.

Referring to FIG. 8, the second bank BNK2 may be disposed on a side surface of the first bank BNK. For example, at least a portion of the second bank BNK2 may be disposed on the side surface of the first bank BNK1 with an insulating layer (for example, the first insulating layer INS1 and the third insulating layer INS3) interposed therebetween. For example, in accordance with this embodiment, the second bank BNK2 may be disposed on both the side surface and a top surface of the first bank BNK1. Although not separately shown in FIG. 8, the second bank BNK2 may be in contact with the color conversion layer CCL. The second bank BNK2 has sufficient liquid repellency in case that the process for forming the color conversion layer CCL is performed, a fluid for providing the color conversion layer CCL can be efficiently diffused, thereby improving process performance. For example, in case that the second bank BNK2 may include an organic material while being disposed on the side surface of the first bank BNK1, the fluid for providing the color conversion layer CCL may have high spreadability.

The second bank BNK2 may be disposed on the first and second reflective electrodes RELT1 and RELT2 disposed on the side surface of the first bank BNK1. Accordingly, the second bank BNK2 may overlap the first and second reflective electrodes RELT1 and RELT2 disposed on the side surface of the first bank BNK1. Also, the second bank BNK2 may include one of the above-described materials, and may be substantially transparent. For example, the second bank BNK2 may include an organic material, and be substantially transparent. Therefore, the second bank BNK2 may allow light to be transmitted therethrough. Accordingly, light emitted from the light emitting element LD can be transmitted through the second bank BNK2 on the side surface of the first bank BNK1 and reflected by the first and second reflective electrodes RELT1 and RELT2. Thus, like as described above, the light emission efficiency of the display device DD can be improved.

In accordance with an embodiment, the first bank BNK1 may have a first width D1′. The second bank BNK2 may have a second width D2′. The first width D1′ and the second width D2′ may mean lengths of the first bank BNK1 and the second bank BNK2 along the direction in which first banks BNK1 (or second banks BNK2) are spaced apart from each other with the light emitting element LD (or the emission area EMA). In accordance with an embodiment, the first width D1′ may be smaller or less than the second width D2′. For example, the first width D1′ is smaller or less than the second width D2′, and a difference between the first width D1′ and the second width D2′ may be about 3 μm or less. By way of example, in an embodiment, the first width D1′ is smaller or less than the second width D2′, and the difference between the first width D1′ and the second width D2′ may be about 2 μm or less. By way of example, in an embodiment, the first width D1′ is smaller or less than the second width D2′, and the difference between the first width D1′ and the second width D2′ may be about 1 μm or less. In case that the first width D1′ and the second width D2′ satisfy one of the above-described numerical ranges, a size of the opening OPN according to the second bank BNK2 can be sufficiently secured, and performance of the process for forming the color conversion layer CCL can be improved as described above.

The sub-pixel SPXL in accordance with the third embodiment will be described with reference to FIG. 9. In FIG. 9, descriptions of portions overlapping those described above may be omitted or simplified.

The sub-pixel SPXL in accordance with the third embodiment may be different from the sub-pixel SPXL in accordance with the first embodiment, in that the first bank BNK1 may be integral with the insulating pattern INP as a single component.

Referring to FIG. 9, the insulating pattern INP may protrude by a height corresponding to the above-described first bank BNK1. As described above, the first and second reflective electrodes RELT1 and RELT2 may be disposed on the insulating pattern INP protruding by a height corresponding to the first bank BNK1 to form a reflective wall. For example, a first part 220 corresponding to the insulating pattern INP in accordance with the first embodiment may be patterned, and a second part 240 corresponding to the first bank BNK1 in accordance with the first embodiment may be patterned, thereby an insulating pattern INP in accordance with the third embodiment. In accordance with an embodiment, in order to form the insulating pattern INP, the first part 220 of the insulating pattern INP may be patterned by using a full-tone mask, and the second part 240 of the insulating pattern INP may be patterned by using a halftone mask. In accordance with this embodiment, the light emission efficiency of the display device DD can be improved while simplifying processes.

In accordance with a third embodiment, the insulating pattern INP may simultaneously perform roles of the insulating pattern INP and the first bank BNK1, which are described above with reference to the first and second embodiments. For example, an ink including the light emitting element LD may be provided in an area surrounded by the insulating pattern INP.

In an embodiment, a width L1 of the first part 220 of the insulating pattern INP may be greater than a width L2 of the second part 240 of the insulating pattern INP. Accordingly, a sufficient height of the insulating pattern INP, so that a wide reflective wall can be formed. The first part 220 expands, so that the position of the light emitting element LD can be clearly defined. In an embodiment, a height of the first part 220 of the insulating pattern INP may be smaller or less than a height of the second part 240 of the insulating pattern INP.

Other components of the pixel PXL including the color conversion layer CCL will be described with reference to FIGS. 10 and 11.

FIG. 10 is a schematic sectional view illustrating first to third sub-pixels in accordance with an embodiment. FIG. 11 is a schematic sectional view illustrating a sub-pixel in accordance with an embodiment.

FIG. 10 illustrates the color conversion layer CCL, the optical layer OPL, the color filter layer CFL, and the like within the spirit and the scope of the disclosure. For convenience of description, in FIG. 10, components except the second bank BNK2 in the pixel circuit layer PCL and the display element layer DPL among the above-described components will be omitted. FIG. 11 illustrates a stacked structure of the pixel PXL in relation to the color conversion layer CCL, the optical layer OPL, and the color filter layer CFL.

Referring to FIGS. 10 and 11, the second bank BNK2 may be disposed between first to third sub-pixels SPXL1, SPXL2, and SPXL3 or at a boundary of the first to third sub-pixels SPXL1, SPXL2, and SPXL3, and define a space (or area) overlapping each of the first to third sub-pixels SPXL1, SPXL2, and SPXL3. The space defined by the second bank BNK2 may be an area in which the color conversion layer CCL can be provided.

The color conversion layer CCL may be disposed above light emitting elements LD in the space surrounded by the second bank BNK2. The color conversion layer CCL may include a first color conversion layer CCL1 disposed in the first sub-pixel SPXL1, a second color conversion layer CCL2 disposed in the second sub-pixel SPXL2, and a light scattering layer LSL disposed in the third sub-pixel SPXL3.

In an embodiment, the first to third sub-pixels SPXL1, SPXL2, and SPXL3 may include light emitting elements LD emitting light of a same color. For example, the first to third sub-pixels SPXL1, SPXL2, and SPXL3 may include light emitting elements LD emitting light of a third color (or blue). The color conversion layer CCL including color conversion particles is disposed on each of the first to third sub-pixels SPXL1, SPXL2, and SPXL3, so that a full-color image can be displayed.

The first color conversion layer CCL1 may include first color conversion particles for converting light of the third color, which is emitted from the light emitting element LD, into light of a first color. For example, the first color conversion layer CCL1 may include first quantum dots QD1 dispersed in a matrix material such as base resin.

In an embodiment, in case that the light emitting element LD is a blue light emitting element emitting light of blue, and the first sub-pixel SPXL1 is a red pixel, the first color conversion layer CCL1 may include a first quantum dot QD1 for converting light of blue, which is emitted from the blue light emitting element, into light of red. The first quantum dot QD1 may absorb blue light and emit red light by shifting a wavelength of the blue light according to energy transition. In case that the first sub-pixel SPXL1 is a pixel of another color, the first color conversion layer CCL1 may include a first quantum dot QD1 corresponding to the color of the first sub-pixel SPXL1.

The second color conversion layer CCL2 may include second color conversion particles for converting light of the third color, which is emitted from the light emitting element LD, into light of a second color. For example, the second color conversion layer CCL2 may include second quantum dots QD2 dispersed in a matrix material such as base resin.

In an embodiment, in case that the light emitting element LD is a blue light emitting element emitting light of blue, and the second sub-pixel SPXL2 is a green pixel, the second color conversion layer CCL2 may include a second quantum dot QD2 for converting light of blue, which is emitted from the blue light emitting element, into light of green. The second quantum dot QD2 may absorb blue light and emit green light by shifting a wavelength of the blue light according to energy transition. In case that the second sub-pixel SPXL2 is a pixel of another color, the second color conversion layer CCL2 may include a second quantum dot QD2 corresponding to the color of the second sub-pixel SPXL2.

In an embodiment, light of blue having a relatively short wavelength in a visible light band is incident into the first quantum dot QD1 and the second quantum dot QD2, so that absorption coefficients of the first quantum dot QD1 and the second quantum dot QD2 can be increased. Accordingly, the efficiency of light finally emitted from the first sub-pixel SPXL1 and the second sub-pixel SPXL2 can be improved, and excellent color reproduction can be ensured. The light emitting unit EMU of each of the first to third sub-pixels SPXL1, SPXL2, and SPXL3 uses light emitting elements of a same color (for example, blue light emitting elements), so that the manufacturing efficiency of the display device can be improved.

The light scattering layer LSL may be provided to efficiently use light of the third color (or blue) emitted from the light emitting element LD. In an example, in case that the light emitting element LD is a blue light emitting element emitting light of blue, and the third sub-pixel SPXL3 is a blue pixel, the light scattering layer LSL may include at least one kind of light scattering particle SCT to efficiently use light emitted from the light emitting element LD. In an example, the light scattering particle SCT of the light scattering layer LSL may include at least one of barium sulfate (BaSO₄), calcium carbonate (CaCO₃), titanium oxide (TiO₂), silicon oxide (SiO₂), aluminum oxide (Al₂O₃), zirconium oxide (ZrO₂), and zinc oxide (ZnO). The light scattering particle SCT is not disposed only in the third sub-pixel SPXL3, and may be selectively included in the first color conversion layer CCL2 or the second color conversion layer CCL2. In an embodiment, the light scattering particle SCT may be omitted such that the light scattering layer LSL including a transparent polymer is provided.

A first capping layer CPL1 may be disposed on the color conversion layer CCL. The first capping layer CPL1 may be provided through the first to third sub-pixels SPXL1, SPXL2, and SPXL3. The first capping layer CPL1 may cover the color conversion layer CCL. The first capping layer CPL1 may prevent the color conversion layer CCL from being damaged or contaminated due to infiltration of an impurity such as moisture or air from the outside.

The first capping layer CPL1 is an inorganic layer, and may include silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), silicon oxynitride (SiOₓN_{y}), and the like within the spirit and the scope of the disclosure.

The optical layer OPL may be disposed on the first capping layer CPL. The optical layer OPL may function to improve light extraction efficiency by recycling light provided from the color conversion layer CCL through total reflection. To this end, the optical layer OPL may have a refractive index relatively lower than a refractive index of the color conversion layer CCL. For example, the refractive index of the color conversion layer may be about 1.6 to about 2.0, and the refractive index of the optical layer OPL may be about 1.1 to about 1.3.

A second capping layer CPL2 may be disposed on the optical layer OPL. The second capping layer CPL2 may be provided throughout the first to third sub-pixels SPXL1, SPXL2, and SPXL3. The second capping layer CPL2 may cover the optical layer OPL. The second capping layer CPL2 may prevent the optical layer OPL from being damaged or contaminated due to infiltration of an impurity such as moisture or air from the outside.

The second capping layer CPL2 is an inorganic layer, and may include silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), silicon oxynitride (SiOₓN_{y}), and the like within the spirit and the scope of the disclosure.

A planarization layer PLL may be disposed on the second capping layer CPL2. The planarization layer PLL may be provided throughout the first to third sub-pixels SPXL1, SPXL2, and SPXL3.

The planarization layer PLL may include an organic material such as acrylic resin, epoxy resin, phenolic resin, polyamide resin, polyimide resin, unsaturated polyester resin, poly-phenylene ether resin, poly-phenylene sulfide resin, or benzocyclobutene (BCB). However, the disclosure is not necessarily limited thereto, and the planarization layer PLL may include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The color filter layer CFL may be disposed on the planarization layer PLL. The color filter layer CFL may include color filters CF1, CF2, and CF3 which accord with a color of each pixel PXL. The color filters CF1, CF2, and CF3 which accord with a color of each of the first to third sub-pixels SPXL1, SPXL2, and SPXL3 are disposed, so that a full-color image can be displayed.

The color filter layer CFL may include a first color filter CF1 disposed in the first sub-pixel SPXL1 to allow light emitted from the first sub-pixel SPXL1 to be selectively transmitted therethrough, a second color filter CF2 disposed in the second sub-pixel SPXL2 to allow light emitted from the second sub-pixel SPXL2 to be selectively transmitted therethrough, and a third color filter CF3 disposed in the third sub-pixel SPXL3 to allow light emitted from the third sub-pixel SPXL3 to be selectively transmitted therethrough.

In an embodiment, the first color filter CF1, the second color filter CF2, and the third color filter CF3 may be respectively a red color filter, a green color filter, and a blue color filter, but the disclosure is not necessarily limited thereto. Hereinafter, in case that an arbitrary color filter among the first color filter CF1, the second color filter CF2, and the third color filter CF3 is designated or in case that two or more kinds of color filters are inclusively designated, the corresponding color filter or the corresponding color filters are referred to as a “color filter CF” or “color filters CF.”

The first color filter CF1 may overlap the first color conversion layer CCL1 in the thickness direction of the substrate SUB (for example, the third direction DR3). The first color filter CF1 may include a color filter material for allowing light of a first color (or red) to be selectively transmitted therethrough. For example, in case that the first sub-pixel SPXL1 is a red pixel, the first color filter CF1 may include a red color filter material.

The second color filter CF2 may overlap the second color conversion layer CCL2 in the thickness direction of the substrate SUB (for example, the third direction DR3). The second color filter CF2 may include a color filter material for allowing light of a second color (or green) to be selectively transmitted therethrough. For example, in case that the second sub-pixel SPXL2 is a green pixel, the second color filter CF2 may include a green color filter material.

The third color filter CF3 may overlap the light scattering layer LSL in the thickness direction of the substrate SUB (for example, the third direction DR3). The third color filter CF3 may include a color filter material for allowing light of a third color (or blue) to be selectively transmitted therethrough. For example, in case that the third sub-pixel SPXL3 is a blue pixel, the third color filter CF3 may include a blue color filter material.

In an embodiment, a light blocking layer BM may be further disposed between the first to third color filters CF1, CF2, and CF3. As described above, in case that the light blocking layer BM is formed between the first to third color filters CF1, CF2, and CF3, a color mixture defect viewed at the front or side of the display device DD can be prevented. The material of the light blocking layer BM is not particularly limited, and the light blocking layer BM may be various light blocking materials. In an example, the light blocking layer BM may be implemented by stacking the first to third color filters CF1, CF2, and CF3.

An overcoat layer OC may be disposed on the color filter layer CFL. The overcoat layer OC may be provided throughout the first to third sub-pixels SPXL1, SPXL2, and SPXL3. The overcoat layer OC may cover a lower member including the color filter layer CFL. The overcoat layer OC may prevent moisture or air from infiltrating into the above-described lower member. Also, the overcoat layer OC may protect the above-described lower member from a foreign matter such as dust.

The overcoat layer OC may include an organic material such as acrylic resin, epoxy resin, phenolic resin, polyamide resin, polyimide resin, unsaturated polyester resin, poly-phenylene ether resin, poly-phenylene sulfide resin, or benzocyclobutene (BCB). However, the disclosure is not necessarily limited thereto, and the overcoat layer OC may include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The outer film layer OFL may be disposed on the overcoat layer OC. The outer film layer OFL may be disposed at an outer portion of the display device DD, to reduce external influence. The outer film layer OFL may be provided throughout the first to third sub-pixels SPXL1, SPXL2, and SPXL3. In an embodiment, the outer film layer OFL may include one of a polyethylenephthalate (PET) film, a low reflective film, a polarizing film, and a transmittance controllable film, but the disclosure is not necessarily limited thereto. In an embodiment, the pixel PXL may include an upper substrate instead of the outer film layer OFL.

In accordance with the embodiment, first light emitted from the light emitting element LD and second light applied through the first quantum dot QD1 (, the second quantum dot QD2, or the light scattering particle SCT) can be recycled by the first and second reflective electrodes RELT1 and RELT2 (see FIG. 11). Consequently, in accordance with the embodiment, the display device DD can be provided, which have improved light emission efficiency while improving process performance.

In accordance with the disclosure, there can be provided a display device having improved light emission efficiency.

Example embodiments have been disclosed herein, and although terms are employed, they are used and are to be interpreted in a generic and descriptive sense only and not for purpose of limitation. In some instances, as would be apparent to one of ordinary skill in the art, features, characteristics, and/or elements described in connection with an embodiment may be used singly or in combination with features, characteristics, and/or elements described in connection with other embodiments unless otherwise indicated. Accordingly, it will be understood by those of ordinary skill in the art that various changes in form and details may be made without departing from the features and scope of the disclosure and as set forth in the following claims.

What is claimed is:

1. A display device comprising:
a first electrode and a second electrode disposed on a substrate;
a first bank disposed on the substrate, the first bank protruding in a thickness direction of the substrate;
a light emitting element disposed on the first electrode and the second electrode;
a reflective electrode disposed on the first bank;
a second bank disposed on the first bank; and
a color conversion layer disposed in an area surrounded by the second bank.

2. The display device of claim 1, wherein the second bank is disposed on a top surface of the first bank and not disposed on any side surface of the first bank.

3. The display device of claim 1, wherein
the first bank has a first height, and
the second bank has a second height, and
the first height is greater than the second height.

4. The display device of claim 3, wherein the second height is about 0.3 times or less than the first height.

5. The display device of claim 1, wherein
the first bank has a first width, and
the second bank has a second width, and
the first width is greater than the second width.

6. The display device of claim 5, wherein a difference between the first width and the second width is about 3 μm or less.

7. The display device of claim 1, further comprising:
an insulating pattern disposed on the substrate, the insulating pattern protruding in the thickness direction of the substrate, wherein
a portion of the reflective electrode is disposed on the insulating pattern,
the insulating pattern includes a first insulating pattern and a second insulating pattern, and
the light emitting element is disposed between the first insulating pattern and the second insulating pattern.

8. The display device of claim 7, wherein
the first bank has a first width,
the second bank has a second width,
the insulating pattern has a third width,
the first width is greater than the second width, and
the third width is greater than the first width.

9. The display device of claim 1, wherein the second bank is disposed on a side surface and a top surface of the first bank first bank.

10. The display device of claim 9, wherein the second bank includes an organic material that transmits light.

11. The display device of claim 9, wherein
the first bank has a first width,
the second bank has a second width, and
the second width is greater than the first width.

12. The display device of claim 11, wherein a difference between the first width and the second width is about 3 μm or less.

13. The display device of claim 1, wherein the light emitting element is disposed in an area surrounded by the first bank.

14. The display device of claim 1, wherein at least a portion of the reflective electrode is disposed between the first bank and the second bank.

15. The display device of claim 1, wherein
the color conversion layer includes a color conversion particle that converts a color of light, and
a surface of the second bank faces the first bank and the reflective electrode, and
another surface of the second bank is exposed toward the color conversion layer.

16. The display device of claim 1, wherein the color conversion layer contacts the second bank.

17. The display device of claim 1, wherein the reflective electrode is disposed on a side surface of the first bank.

18. The display device of claim 1, further comprising:
a color filter layer disposed on the color conversion layer, the color filter layer selectively transmits light.

19. A display device comprising:
a first electrode and a second electrode disposed on a substrate;
a partition wall disposed on the substrate, the partition wall protruding in a thickness direction of the substrate;
a light emitting element disposed between the first electrode and the second electrode;
a reflective electrode disposed on the partition wall;
a bank disposed on the partition wall; and
a color conversion layer disposed in an area surrounded by the bank, wherein
the partition wall includes a first part and a second part, and
a width of the first part of the partition wall is greater than a width of the second part of the partition wall.

20. The display device of claim 19, wherein a height of the first part of the partition wall is less than a height of the second part of the partition wall.
